(19) United States
(12) Patent Application Publication
(10) Pub. No.: US 2024/0072744 A1
(43) Pub. Date: Feb. 29, 2024

(54) Differential Input Circuit and Amplifier

(71) Applicant: ROHM CO., LTD., Kyoto (JP)

(72) Inventor: Masaki ASAKAWA, Kyoto (JP)

(21) Appl. No.: 18/454,353

(22) Filed: Aug. 23, 2023

(30) Foreign Application Priority Data
Aug. 30, 2022 (JP) 2022-137078

(51) Int. Cl. H03F 3/45

(52) U.S. Cl. CPC H03F 3/45183; H03F 3/45273; H03F 2203/45238

(57) ABSTRACT

The present disclosure provides a differential input circuit. The differential input circuit includes: a P-channel FET differential input pair; an N-channel FET differential input pair; a first power line configured to receive a first voltage; a second power line configured to receive a second voltage lower than the first voltage; a first P-channel FET; a constant current source (CS1) disposed between the first power supply line and the P-channel FET differential input pair as well as the first P-channel FET; a current mirror circuit disposed between the first P-channel FET as well as the N-channel FET differential input pair and the second power supply line; and a logic circuit configured to supply a binarized logic signal to a gate of the first P-channel FET.

### TECHNICAL FIELD

The present disclosure relates to a differential input circuit and an amplifier having the differential input circuit.

### BACKGROUND

In the prior art, it is acknowledged that a differential input circuit shown in FIG. 10 can function as a differential input circuit capable of implementing rail-to-rail input (for example, refer to non-patent publication 1).

The differential input circuit shown in FIG. 10 includes input terminals T11 and T12, a P-channel metal oxide semiconductor (PMOS) differential input pair consisting of PMOS transistors Q11 and Q12, and an N-channel metal oxide semiconductor (NMOS) differential input pair consisting of transistors Q13 and Q14. The input terminal T11 is connected to a gate of each of the PMOS transistor Q11 and the NMOS transistor Q13. The input terminal T12 is connected to a gate of each of the PMOS transistor Q12 and the NMOS transistor Q14.

The differential input circuit in FIG. 10 further includes a power supply line LN11 configured to receive a voltage VDD, a power supply line LN12 configured to receive a voltage VSS lower than the voltage VDD, a constant current source CS11 disposed between the power supply line LN11 and the PMOS differential input pair, and a constant current source CS12 disposed between the NMOS differential input pair and the power supply line LN12.

### PRIOR ART DOCUMENT

### Non-Patent Publication

[Non-patent publication 1] Taniguchi Kenji, “CMOS Analog Circuit Gate Entry for LSI Designers”, 3rd Edition, CQ Publishing Co., Ltd., Sep. 1, 2005, p. 202.

### BRIEF DESCRIPTION OF THE DRAWINGS

FIG. 1 is a diagram of an amplifier of a comparison example.

FIG. 2 is a diagram of various operation ranges of a PMOS differential input pair and an NMOS differential input pair of a differential input circuit disposed in the amplifier shown in FIG. 1.

FIG. 3 is a diagram of an amplifier according to an embodiment.

FIG. 4 is a diagram of phase margin characteristics of the amplifier shown in FIG. 1 and the amplifier shown in FIG. 3.

FIG. 5 is a diagram of current characteristics of a differential input circuit disposed in the amplifier shown in FIG. 1.

FIG. 6 is a diagram of current characteristics of a differential input circuit disposed in the amplifier shown in FIG. 3.

FIG. 7 is a diagram of output voltage characteristics of the amplifier shown in FIG. 1 and the amplifier shown in FIG. 3.

FIG. 8 is a diagram of current characteristics of a differential input circuit disposed in the amplifier shown in FIG. 1.

FIG. 9 is a diagram of current characteristics of a differential input circuit disposed in the amplifier shown in FIG. 3.

FIG. 10 is a diagram of a conventional differential input circuit.

FIG. 11 is a diagram of various operation ranges of a PMOS differential input pair and an NMOS differential input pair of a differential input circuit shown in FIG. 10.

### DETAILED DESCRIPTION OF THE EMBODIMENTS

In the present disclosure, a metal oxide semiconductor (MOS) transistor refers to a field effect transistor in which a gate is structured to have at least three layers including “a layer containing a conductor or a semiconductor such as polysilicon with a small resistance value”, “an insulating layer”, and “a P-type, N-type or intrinsic semiconductor layer”. That is to say, the gate structure of the MOS transistor is not limited to the structure of the three layers including metal, oxide and semiconductor.

In the present disclosure, a constant current source refers to a current source that outputs a constant current. In the present disclosure, a constant current means a fixed current in an ideal state, and is in practice a current that may vary slightly in response to temperature changes.

### <Amplifier (Comparison Example)>

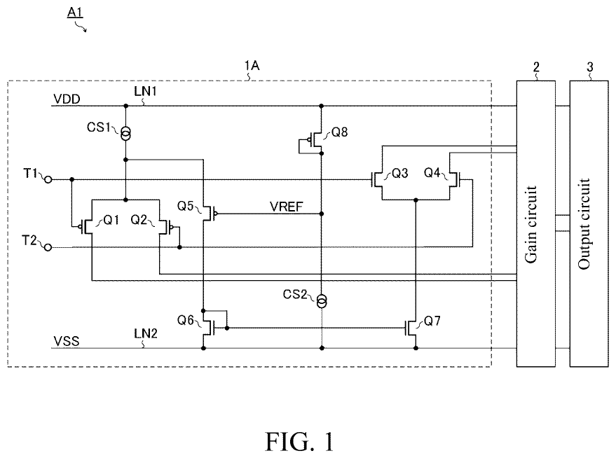

FIG. 1 shows a diagram of an amplifier of a comparison example (equivalent to a general configuration example to be compared with embodiments described later).

An amplifier A1 of the comparison example includes a differential input circuit 1A, a gain circuit 2 and an output circuit 3. The gain circuit 2 is disposed at a rear end of the differential input circuit 1A. The output circuit 3 is disposed at a rear end of the gain circuit 2.

The differential input circuit 1A includes input terminals T1 and T2, a PMOS differential input pair consisting of PMOS transistors Q1 and Q2, and an NMOS differential input pair consisting of NMOS transistors Q3 and Q4. The input terminal T1 is connected to a gate of each of the PMOS transistor Q1 and the NMOS transistor Q3. The input terminal T2 is connected to a gate of each of the PMOS transistor Q2 and the NMOS transistor Q4.

The differential input circuit 1A further includes a power supply line LN1, a power supply line LN2, a PMOS transistor Q5, a constant current source CS1, and a current minor circuit formed by NMOS transistors Q6 and Q7.

The power supply line LN1 is configured to receive a voltage VDD. The power supply line LN2 is configured to receive a voltage VSS lower than the voltage VDD.

The constant current source CS1 is disposed between the PMOS transistor Q5 and the power supply line LN1, and between the PMOS differential input pair and the PMOS transistor Q5. A first terminal of the constant current source CS1 is connected to the power supply line LN1. A second terminal of the constant current source CS1 is connected to a source of each of the PMOS transistors Q1, Q2 and Q5.

The current mirror circuit formed by the NMOS transistors Q6 and Q7 is disposed between the PMOS transistor Q5 and the power supply line LN2, and between the NMOS differential input pair and the power supply line LN2. A gate and a drain of the NMOS transistor Q6 and a gate of the NMOS transistor Q7 are connected to a drain of the PMOS transistor Q5. A drain of the NMOS transistor Q7 is connected to a drain of each of the NMOS transistors Q3 and Q4. A source of each of the NMOS transistors Q6 and Q7 is connected to the power supply line LN2.

The differential input circuit 1A further includes a PMOS transistor Q8 and a constant current source CS2. A source of the PMOS transistor Q8 is connected to the power supply line LN1. A gate and a drain of the PMOS transistor Q8 are connected to a gate of the PMOS transistor Q5 and a first terminal of the constant current source CS2. A second terminal of the constant current source CS2 is connected to the power supply line LN2.

The PMOS transistor Q8 and the constant current source CS2 are configured to generate a reference voltage VREF, and to supply the reference voltage VREF to a gate of the PMOS transistor Q5. The reference voltage VREF becomes a value corresponding to the voltage VDD and a characteristic of the PMOS transistor Q8. More specifically, the reference voltage VREF becomes a value corresponding to the voltage VDD and a gate-source voltage of the PMOS transistor Q8. Accordingly, the reference voltage VREF can be set to a value corresponding to characteristics of PMOS transistors in the differential input circuit 1A.

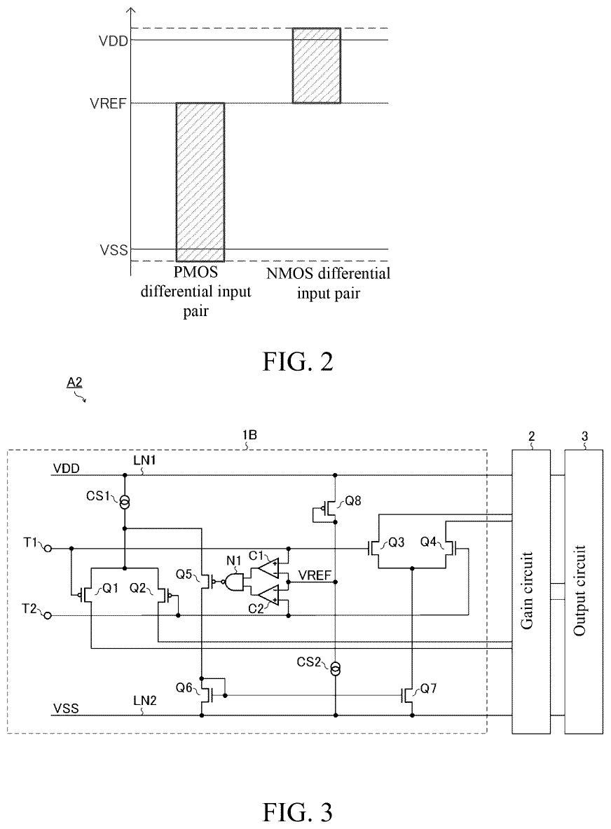

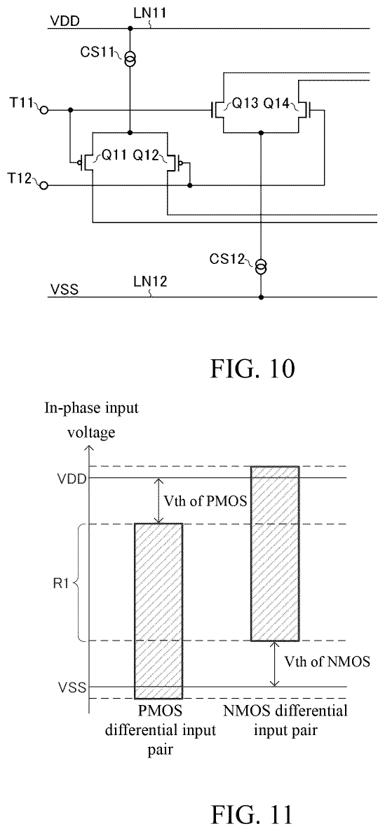

In the differential input circuit 1A, as shown in FIG. 2, the PMOS differential input pair operates when an in-phase input voltage is less than the reference voltage VREF, and the NMOS differential input pair operates when the in-phase input voltage is greater than the reference voltage VREF. That is to say, in the differential input circuit 1A, there is not any in-phase input voltage region in which the PMOS differential input pair and the NMOS differential input pair operate simultaneously. Thus, the operation stability of the differential input circuit 1A is better than that of the differential input circuit shown in FIG. 10.

However, when the in-phase input voltage is equal to or substantially equal to the reference voltage VREF, since the PMOS differential input pair and the NMOS differential input pair of the differential input circuit 1A share the current output from the constant current source CS1, the amplification ratio may be unstable and the operation stability may be degraded.

The size of the current that can be supplied to the NMOS differential input pair is limited by the current capability of the PMOS transistor Q5. The current capability of the PMOS transistor Q5 is dependent on the size of the PMOS transistor Q5 and the gate-source voltage of the PMOS transistor Q5. In the differential input circuit 1A, the gate-source voltage of the PMOS transistor Q5 cannot be increased because the gate voltage of the PMOS transistor Q5 becomes the reference voltage VREF. Thus, in the differential input circuit 1A, the size of the PMOS transistor Q5 needs to be increased.

However, as the size of the PMOS transistor Q5 increases, a gate-source parasitic capacitance and a gate-drain parasitic capacitance of the PMOS transistor Q5 also increase, such that high-speed switching between the operations of the PMOS differential input pair and the operations of the NMOS differential input pair cannot be realized.

In view of the concern above, a differential input circuit having operation stability better than that of the differential input circuit 1A is provided according to a novel embodiment below.

### <Amplifier (Embodiment)>

FIG. 3 shows a diagram of an amplifier according to an embodiment. In FIG. 3, detailed description for the same parts in FIG. 1 denoted with the same numerals or symbols is omitted for brevity.

An amplifier A2 according to the embodiment includes a differential input circuit 1B, a gain circuit 2 and an output circuit 3. The gain circuit 2 is disposed at a rear end of the differential input circuit 1B. The output circuit 3 is disposed at a rear end of the gain circuit 2.

The differential input circuit 1B is configured to additionally include comparators C1 and C2 and a NAND gate N1 in comparison with the differential input circuit 1A (referring to FIG. 1).

A non-inverting input terminal of the comparator C1 is connected to an input terminal T1. An inverting input terminal of the comparator C1 receives a reference voltage VREF. A non-inverting input terminal of the comparator C2 is connected to an input terminal T2. An inverting input terminal of the comparator C2 receives the reference voltage VREF.

An output terminal of the comparator C1 is connected to a first input terminal of the NAND gate N1. An output terminal of the comparator C2 is connected to a second input terminal of the NAND gate N1. An output terminal of the NAND gate N1 is connected to a gate of the PMOS transistor Q5. When an in-phase input voltage is less than the reference voltage VREF, the NAND gate N1 provides a logic signal at a high level (equivalent to the voltage VDD) to the gate of the PMOS transistor Q5. On the other hand, when the in-phase input voltage is greater than the reference voltage VREF, the NAND gate N1 provides a logic signal at a low level (equivalent to the voltage VSS) to the gate of the PMOS transistor Q5.

In the differential input circuit 1B, similar to the differential input circuit 1A, as shown in FIG. 2, the PMOS differential input pair operates when the in-phase input voltage is less than the reference voltage VREF, and the NMOS differential input pair operates when the in-phase input voltage is greater than the reference voltage VREF. That is to say, in the differential input circuit 1B, the same as the differential input circuit 1A, there is not any in-phase input voltage region in which the PMOS differential input pair and the NMOS differential input pair operate simultaneously. Thus, the same as the differential input circuit 1A, the operation stability of the differential input circuit 1B is better than that of the differential input circuit shown in FIG. 10.

Moreover, in the differential input circuit 1B, on/off of the PMOS transistor Q5 is controlled via the logic signal output from the NAND gate N1. Thus, in the differential input circuit 1B, there is not any in-phase input voltage region in which the PMOS differential input pair and the NMOS differential input pair share the current output from the constant current source CS1. As a result, in the differential input circuit 1B, even if the in-phase input voltage is equal to or substantially equal to the reference voltage VREF, the operation stability does not deteriorate.

Moreover, because the differential input circuit 1B is different from the differential input circuit 1A in that the gate voltage of the PMOS transistor Q5 is the voltage VSS when the PMOS transistor Q5 is turned on, the gate-source voltage when the PMOS transistor Q5 is turned on can be increased. Thus, in the differential input circuit 1B, the size of the PMOS transistor Q5 can be decreased.

Since the size of the PMOS transistor Q5 in the differential input circuit 1B can be decreased, a gate-source parasitic capacitance and a gate-drain parasitic capacitance of the PMOS transistor Q5 are also decreased, and in so doing high-speed switching between the operations of the PMOS differential input pair and the operations of the NMOS differential input pair can be realized.

Although there is a concern for an increased circuit area for the differential input circuit 1B in a configuration formed by adding the comparators C1 and C2 and the NAND gate N1 to the differential input circuit 1A, as described above, the size of the PMOS transistor Q5 can be decreased, and therefore the circuit area is not significantly increased in comparison with the differential input circuit 1A.

### <Comparison Result Between Comparison Example and Embodiment>

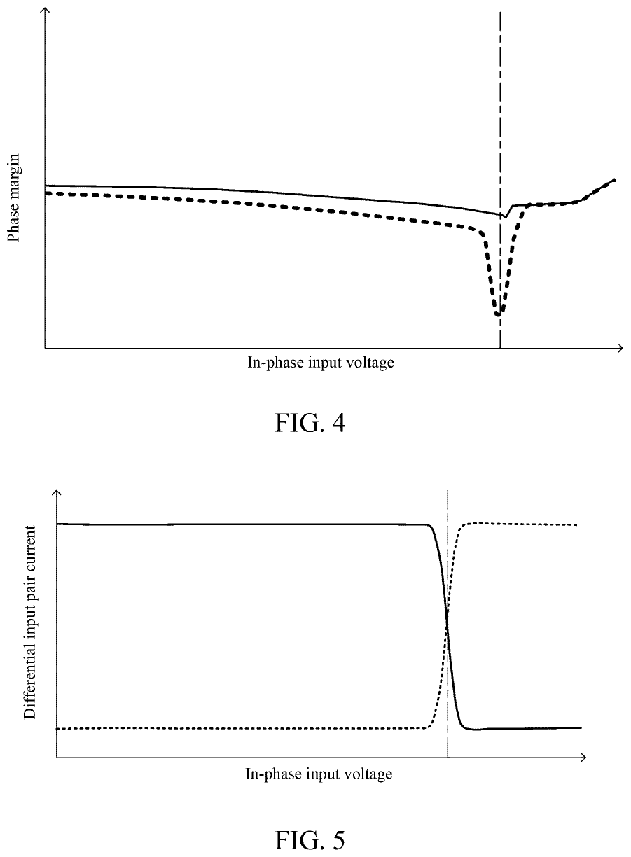

FIG. 4 shows a diagram of phase margin characteristics of the amplifier A1 of the comparison example and the amplifier A2 of the embodiment. In FIG. 4, the vertical axis represents the phase margin and the horizontal axis represents the in-phase input voltage. In FIG. 4, the phase margin characteristic of the amplifier A1 of the comparison example is depicted by a dashed line, and the phase margin characteristic of the amplifier A2 of the embodiment is depicted by a solid line. The dash-dotted line in FIG. 4 represents a situation in which the in-phase input voltage is equal to the reference voltage VREF.

When the in-phase input voltage of the amplifier A1 of the comparison example is equal to or substantially equal to the reference voltage VREF, the phase margin decreases and the operation stability deteriorates. On the other hand, in the amplifier A2 of the embodiment, even when the in-phase input voltage is equal to or substantially equal to the reference voltage VREF, the phase margin almost does not decrease and the operation stability does not deteriorate.

FIG. 5 shows a diagram of current characteristics of the differential input circuit 1A. In FIG. 5, the vertical axis represents the current flowing through the differential input pair, and the horizontal axis represents the in-phase input voltage. In FIG. 5, the characteristic of the current flowing through the PMOS differential input pair is depicted by a solid line, and the characteristic of the current flowing through the NMOS differential input pair is depicted by a dotted line. The dash-dotted line in FIG. 5 represents a situation in which the in-phase input voltage is equal to the reference voltage VREF.

Thus, in the differential input circuit 1A, an in-phase input voltage region in which the PMOS differential input pair and the NMOS differential input pair share the current is present.

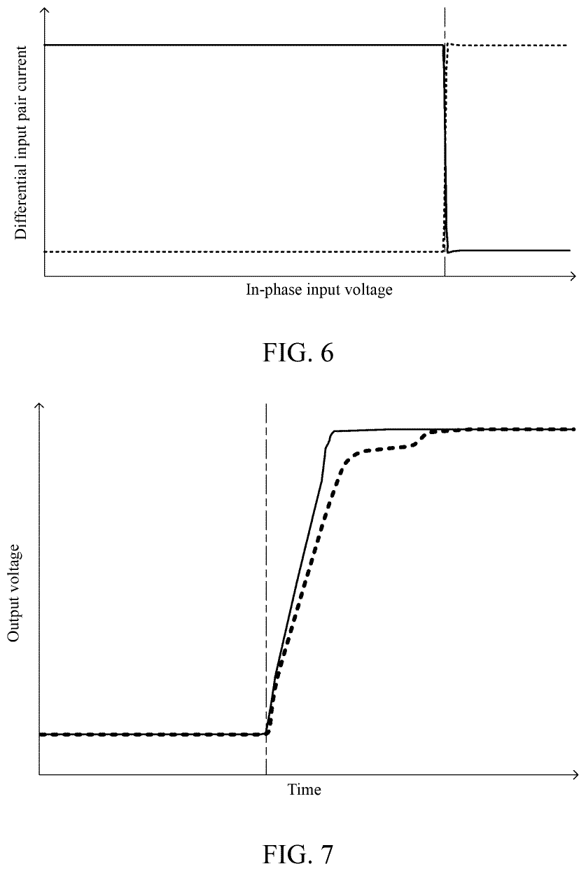

FIG. 6 shows a diagram of current characteristics of the differential input circuit 1B. In FIG. 6, the vertical axis represents the current flowing through the differential input pair, and the horizontal axis represents the in-phase input voltage. In FIG. 6, the characteristic of the current flowing through the PMOS differential input pair is depicted by a solid line, and the characteristic of the current flowing through the NMOS differential input pair is depicted by a dotted line. The dash-dotted line in FIG. 6 represents a situation in which the in-phase input voltage is equal to the reference voltage VREF.

In the differential input circuit 1B, there is not any in-phase input voltage region in which the PMOS differential input pair and the NMOS differential input pair share the current.

FIG. 7 shows a diagram of output voltage characteristics of the amplifier A1 of the comparison example and the amplifier A2 of the embodiment. In FIG. 7, the vertical axis represents the output voltage of the amplifier and the horizontal axis represents time. In FIG. 7, the output voltage characteristic of the amplifier A1 of the comparison example is depicted by a dashed line, and the output voltage characteristic of the amplifier A2 of the embodiment is depicted by a solid line. The dash-dotted line in FIG. 7 represents, in a voltage follower circuit connecting an input terminal (inverting input terminal) T2 with an output, the timing of switching from a first state in which an input terminal (non-inverting input terminal) T1 receives a voltage VSS to a second state in which the input terminal (non-inverting input terminal) T1 receives a voltage VDD.

In the amplifier A1 of the comparison example, rising of the output voltage stagnates temporarily. Thus, a rate at which the output voltage passes through when the first state in which the input terminal (non-inverting input terminal) T1 receives the voltage VSS switches to the second state in which the input terminal (non-inverting input terminal) T1 receives the voltage VDD becomes slow. On the other hand, in the amplifier A2 of the embodiment, rising of the output voltage does not stagnate. Thus, a rate at which the output voltage passes through when the first state in which the input terminal (non-inverting input terminal) T1 receives the voltage VS S switches to the second state in which the input terminal (non-inverting input terminal) T1 receives the voltage VDD becomes fast.

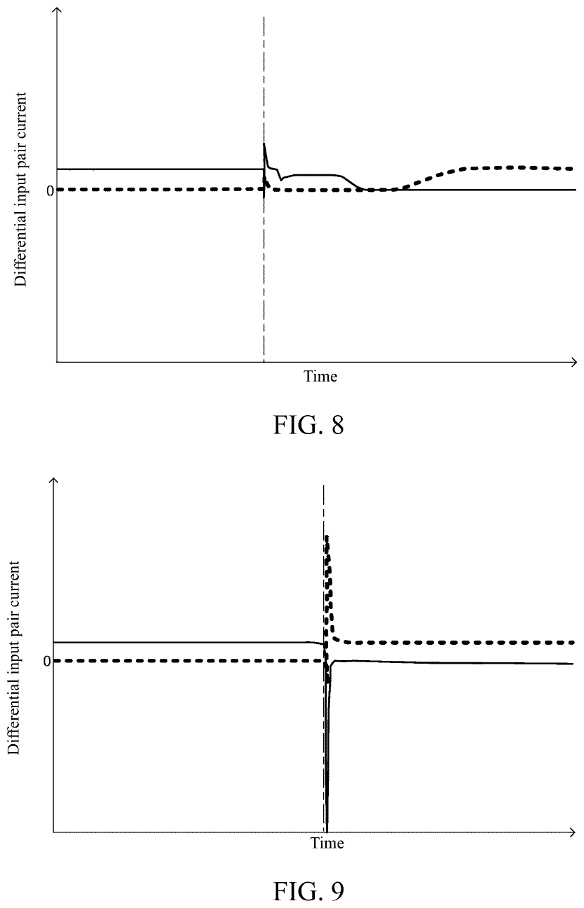

FIG. 8 shows a diagram of current characteristics of the differential input circuit 1A. In FIG. 8, the vertical axis represents the current flowing through the differential input pair, and the horizontal axis represents time. In FIG. 8, the characteristic of the current flowing through the PMOS differential input pair is depicted by a solid line, and the characteristic of the current flowing through the NMOS differential input pair is depicted by a dashed line. The dash-dotted line in FIG. 8 represents, in a voltage follower circuit connecting an input terminal (inverting input terminal) T2 with an output, the timing of switching from a first state in which an input terminal (non-inverting input terminal) T1 receives a voltage VSS to a second state in which the input terminal (non-inverting input terminal) T1 receives a voltage VDD.

In the differential input circuit 1A, when the first state in which the input terminal (non-inverting input terminal) T1 receives the voltage VSS switches to the second state in which the input terminal (non-inverting input terminal) T1 receives the voltage VDD, a time at which the current does not pass between the PMOS differential input pair and the NMOS differential input pair is present. Thus, in the amplifier A1 of the comparison example, rising of the output voltage stagnates temporarily.

FIG. 9 shows a diagram of current characteristics of the differential input circuit 1B. In FIG. 9, the vertical axis represents the current flowing through the differential input pair, and the horizontal axis represents time. In FIG. 9, the characteristic of the current flowing through the PMOS differential input pair is depicted by a solid line, and the characteristic of the current flowing through the NMOS differential input pair is depicted by a dashed line. The dash-dotted line in FIG. 9 represents, in a voltage follower circuit connecting an input terminal (inverting input terminal) T2 with an output, the timing of switching from a first state in which an input terminal (non-inverting input terminal) T1 receives a voltage VSS to a second state in which the input terminal (non-inverting input terminal) T1 receives a voltage VDD.

In the differential input circuit 1B, when the first state in which the input terminal (non-inverting input terminal) T1 receives the voltage VSS switches to the second state in which the input terminal (non-inverting input terminal) T1 receives the voltage VDD, there is not any time at which the current does not pass between the PMOS differential input pair and the NMOS differential input pair. Thus, in the amplifier A2 of the embodiment, rising of the output voltage does not stagnate.

### <Other>

Various modifications may be appropriately made to the embodiments of the present disclosure within the scope of the technical concept of the claims. The embodiments above are only examples of possible implementation forms of the present disclosure, and the meanings of the terms of the present disclosure or the constituents are not limited to the meanings of the terms specified in the embodiments above.

For example, in the embodiments, MOS transistors are used; however, junction field effect transistors may also be used in substitution for MOS transistors.

### <Notes>

A note is attached to the present disclosure which illustrates specific configuration examples by means of the embodiments above.

A differential input circuit (1B) of the present disclosure is configured as (a first configuration) comprising: a P-channel field effect transistor (FET) differential input pair (Q1, Q2); an N-channel FET differential input pair (Q3, Q4); a first power supply line (LN1), configured to receive a first voltage; a second power supply line (LN2), configured to receive a second voltage lower than the first voltage; a first P-channel FET (Q5); a constant current source (CS1), disposed between the first power supply line (LN1) and the P-channel FET differential input pair (Q1, Q2), and between the first power supply line (LN1) and the first P-channel field effect transistor (Q5); a current minor circuit (Q6, Q7), disposed between the first P-channel FET (Q5) and the second power supply line (LN2), and between the N-channel FET differential input pair (Q3, Q4) and the second power supply line (LN2); and a logic circuit (N1), configured to supply a binarized logic signal to a gate of the first P-channel FET.

The differential input circuit of the first configuration may be further configured as (a second configuration), wherein a high level of the logic signal is the first voltage, and a low level of the logic signal is the second voltage.

The differential input circuit of the first or second configuration may be further configured as (a third configuration) further comprising: a first comparator (C1), configured to compare a first input voltage and a reference voltage; and a second comparator (C2), configured to compare a second input voltage and the reference voltage, wherein the logic circuit is configured to receive an output of the first comparator and an output of the second comparator.

The differential input circuit of the third configuration may be further configured as (a fourth configuration), wherein the logic circuit is a NAND gate.

The differential input circuit of the third or fourth configuration may be further configured as (a fifth configuration) further comprising a second P-channel FET (Q8), wherein the reference voltage is a value corresponding to the first voltage and a characteristic of the second P-channel FET.

The differential input circuit of the fifth configuration may be further configured as (a sixth configuration), wherein the reference voltage has a value corresponding to the first voltage and a gate-source voltage of the second P-channel FET.

An amplifier (A2) of the present disclosure is configured as (a seventh configuration) including the differential input circuit according to any one of the first to sixth configurations.

1. A differential input circuit, comprising:
a P-channel field effect transistor (FET) differential input pair;
an N-channel FET differential input pair;
a first power supply line, configured to receive a first voltage;
a second power supply line, configured to receive a second voltage lower than the first voltage;
a first P-channel FET;
a constant current source, disposed between the first power supply line and the P-channel FET differential input pair, and between the first power supply line and the first P-channel field effect transistor;
a current mirror circuit, disposed between the first P-channel FET and the second power supply line, and between the N-channel FET differential input pair and the second power supply line; and
a logic circuit, configured to supply a binarized logic signal to a gate of the first P-channel FET.

2. The differential input circuit of claim 1, wherein a high level of the logic signal is the first voltage, and a low level of the logic signal is the second voltage.

3. The differential input circuit of claim 1, further comprising:
a first comparator, configured to compare a first input voltage and a reference voltage; and
a second comparator, configured to compare a second input voltage and the reference voltage, wherein the logic circuit is configured to receive an output of the first comparator and an output of the second comparator.

4. The differential input circuit of claim 3, wherein the logic circuit is a NAND gate.

5. The differential input circuit of claim 3, further comprising a second P-channel FET, wherein the reference voltage is a value corresponding to the first voltage and a characteristic of the second P-channel FET.

6. The differential input circuit of claim 5, wherein the reference voltage has a value corresponding to the first voltage and a gate-source voltage of the second P-channel FET.

7. An amplifier, comprising the differential input circuit of claim 1.

8. An amplifier, comprising the differential input circuit of claim 2.
